(19) United States
(12) Patent Application Publication
(10) Pub. No.: US 2008/0315277 A1
(43) Pub. Date: Dec. 25, 2008

(54) SEMICONDUCTOR DEVICE

(75) Inventor: Yasutaka NAKASHIBA, Kanagawa (JP)

Correspondence Address: YOUNG & THOMPSON, 209 Madison Street, Suite 500, ALEXANDRIA, VA, 22314, US

(73) Assignee: NEC ELECTRONICS CORPORATION, KANAGAWA (JP)

(21) Appl. No.: 12/103,729

(22) Filed: Apr. 16, 2008

(30) Foreign Application Priority Data
Apr. 16, 2007 (JP) 2007-107327

(51) Int. Cl. H01L 27/06

(52) U.S. Cl. 257/312; 257/E27.016

(57) ABSTRACT

A semiconductor device 1 includes MOS transistors 10 and 70 and a MOS varactor 20. The transistors 10 and 70 and the varactor 20 are formed in the same semiconductor substrate 30. The gate insulating films 15 and 75 of the transistors 10 and 70 are the thinnest gate insulating films in the gate insulating films of the transistor formed in the semiconductor substrate 30. The thickness of the gate insulating film 25 of the varactor 20 is larger than the thickness of the gate insulating films 15 and 75.

This application is based on Japanese patent application No. 2007-107,327, the content of which is incorporated hereinto by reference.

### BACKGROUND

1. Technical Field

The present invention relates to a semiconductor device.

2. Related Art

FIG. 3 is a cross-sectional view, illustrating a conventional semiconductor device. In a conventional semiconductor device 100, transistors 120 and 140 and a varactor 130 are formed on a p type semiconductor substrate 110. The transistors 120 and 140 and the varactor 130 are all the metal-oxide-semiconductor (MOS) type. The transistor 120 is a p channel type, and includes an n type Well region 121, a p+ type diffusion layer 122, an n+ type diffusion layer 123, a gate insulating film 124 and a gate electrode 125. The diffusion layer 122 functions as a source-drain region of the transistor 120. The transistor 140 is an n channel transistor, and includes a p type well region 141, n+ type diffusion layers 142, a p+ type diffusion layer 143, a gate insulating film 144 and a gate electrode 145. The diffusion layer 142 functions as a source-drain region of the transistor 140. The varactor 130 includes an n type well region 131, n+ type diffusion layers 132, a gate insulating film 134 and a gate electrode 135. The gate insulating films 124 and 144 of the transistors 120 and 140 are formed simultaneously at the same time as the gate insulating film 134 of varactor 130 is formed, and these films have the same thickness.

Prior art documents related to the present invention include: Japanese Patent Laid-Open No. 2004-311,858; Japanese Patent Laid-Open No. 2004-214,408; Japanese Patent Laid-Open No. 2004-235,577; Japanese Patent Laid-Open No. 2004-229,102; and Ali Hajimiri et al., “Design Issues in CMOS Differential LC Oscillators”, IEEE JOURNAL OF SOLID-STATE CIRCUITS, Vol. 34, No. 5, May 1999, pp. 717 to 724.

The present inventor has recognized as follows. A tuning sensitivity of the varactor (ΔC/ΔV) is increased as the thickness of the gate insulating film of the varactor is thinner, as shown in FIG. 4. Therefore, an effort for actively providing a thinner thickness of a gate insulating film of a varactor has been made in the conventional technology (for example, see Japanese Patent Laid-Open No. 2004-311,858). In FIG. 4, ordinate represents a capacitance C (arbitrary scaling), and abscissa represents a gate voltage V (arbitrary scaling). Line C1 and line C2 represent results of cases for employing a gate insulating film of a varactor having a thickness of 2.0 nm and having a thickness of 1.4 nm, respectively.

However, since an excessively higher tuning sensitivity causes an excessive change in the capacitance for smaller change of the gate voltage, a problem of a difficulty in achieving a fine tuning of the capacitance is arisen. In recent years, such problem manifests due to a progressively thinner thickness of the gate insulating film by evolutions in the process for manufacturing the semiconductor devices.

### SUMMARY

According to one aspect of the present invention, there is provided a semiconductor device, comprising: a MOS type transistor provided in a semiconductor substrate; and a MOS type varactor provided in the semiconductor substrate; wherein a gate insulating film of the varactor is thicker than the thinnest gate insulating film in gate insulating films of the transistor.

In this semiconductor device, the gate insulating film of the varactor is formed to be thicker than the thinnest gate insulating film among the gate insulating films of the transistor. This allows avoiding an excessively thinner thickness of the gate insulating film of the varactor beyond necessity, even if the reduction in the thickness of the gate insulating film of the transistor is progressed. More specifically, an excessively higher tuning sensitivity of the varactor can be avoided.

According to the present invention, a semiconductor device comprising a varactor, which allows easily achieving a fine tuning of a capacitance, is achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view, illustrating an embodiment of a semiconductor device according to the present invention;

FIG. 2 is a circuit schematic, illustrating LC-VCO provided with a varactor;

FIG. 3 is a cross-sectional view, illustrating a conventional semiconductor device; and

FIG. 4 is a graph showing a relationship of a capacitance of a varactor over agate voltage.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Exemplary implementations according to the present invention will be described in reference to the annexed figures. In all figures, an identical numeral is assigned to an element commonly appeared in the figures, and the detailed description thereof will not be repeated.

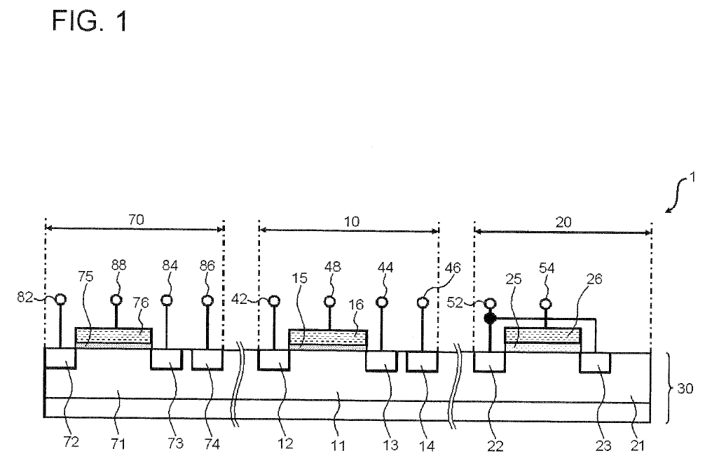

FIG. 1 is a cross-sectional view, illustrating an embodiment of a semiconductor device according to the present invention. A semiconductor device 1 includes transistors 10 and 70 and a varactor 20. The transistors 10 and 70 are metal oxide semiconductor (MOS) field effect transistors (MOSFET). The varactor 20 is a MOS type varactor. The transistors 10 and 70 and the varactor 20 are formed in the same semiconductor substrate 30. In the present embodiment, the semiconductor substrate 30 is a p type silicon substrate.

The transistor 10 is a p channel transistor, and includes an n type well region 11, a p+ type diffusion layers 12 and 13, an n+ type diffusion layer 14, a gate insulating film 15 and a gate electrode 16. The well region 11 is formed in the semiconductor substrate 30. The diffusion layers 12, 13 and 14 are formed in the well region 11. The diffusion layers 12 and 13 function as source-drain regions of the transistor 10. The diffusion layer 12 and 13 are coupled to source-drain terminals 42 and 44, respectively. The diffusion layer 14 is also coupled to a well terminal 46. The well terminal 46 is electrically coupled to the well region 11 through the diffusion layer 14. The gate insulating film 15 is the thinnest gate insulating film in the gate insulating films of the transistor formed in the semiconductor substrate 30. The gate electrode 16 is provided over the semiconductor substrate 30 through the gate insulating film 15. The gate electrode 16 is coupled to the gate terminal 48.

The transistor 70 is an n channel transistor, and includes a p type well region 71, n+ type diffusion layers 72 and 73, a p+ type diffusion layer 74, a gate insulating film 75 and a gate electrode 76. The well region 71 is formed in the semiconductor substrate 30. The diffusion layers 72, 73 and 74 are formed in the well region 71. The diffusion layers 72 and 73 function as source-drain regions of the transistor 70. The diffusion layer 72 and 73 are coupled to source-drain terminals 82 and 84, respectively. The diffusion layer 74 is also coupled to a well terminal 86. The well terminal 86 is electrically coupled to the well region 11 through the diffusion layer 74. The gate insulating film 75 is the thinnest gate insulating film in the gate insulating films of the transistor formed in the semiconductor substrate 30. The gate electrode 76 is provided over the semiconductor substrate 30 through the gate insulating film 75. The gate electrode 76 is coupled to the gate terminal 88.

The varactor 20 includes an n type well region 21, an n+ type diffusion layer 22 (first diffusion layer), an n+ type diffusion layer 23 (second diffusion layer), a gate insulating film 25 and a gate electrode 26. The well region 21 is formed in the semiconductor substrate 30. The diffusion layers 22 and 23 are formed in the well region 21. The diffusion layer 22 is provided in one side of the gate electrode 26, and the diffusion layer 23 is provided in the other side of gate electrode 26. The diffusion layers 22 and 23 are coupled to a common well terminal 52. In other words, the diffusion layer 22 and 23 are mutually electrically coupled. Well terminal 52 is electrically coupled with well region 21 through diffusion layers 22 and 23. The gate electrode 26 is provided on the semiconductor substrate 30 through the gate insulating film 25. The gate electrode 26 is coupled to the gate terminal 54. A capacitance of the varactor 20 can be changed by changing a gate voltage, or in other words a voltage applied between the well terminal 52 and the gate terminal 54.

The thickness of the gate insulating film 25 of the varactor 20 is larger than the thicknesses of the gate insulating films 15 and 75. Typical thicknesses of the gate insulating films 15 ad 75 are, for example, 1.4 nm. Typical thickness of the gate insulating film 25 is, for example, 2.0 nm.

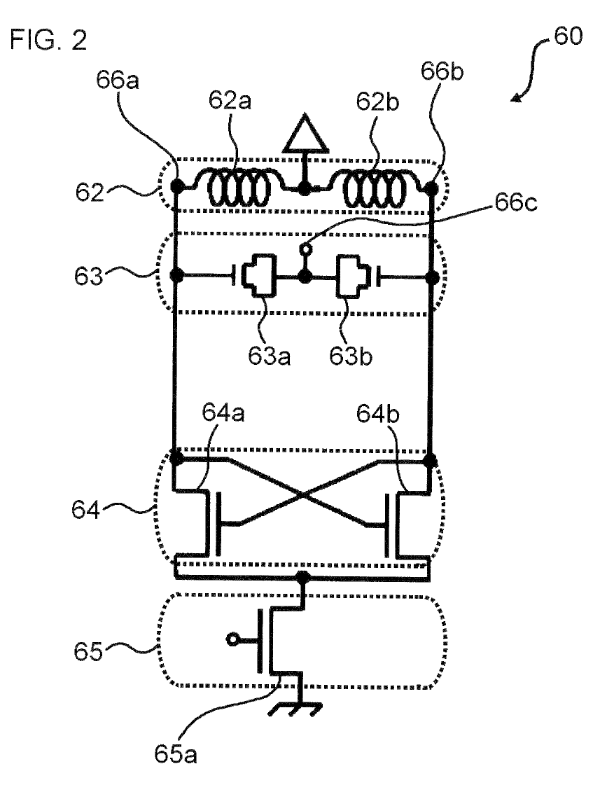

FIG. 2 is a circuit schematic, illustrating an LC resonance-voltage controlled oscillator (LC-VCO) provided with a varactor. The LC-VCO 60 is provided in, for example, a system on a chip (SOC) structure. The LC-VCO 60 is coupled between an electrical power source and a ground. The LC-VCO 60 is provided with an inductor portion 62, a variable capacitor portion 63, a negative resistor portion 64 and an electric current regulator portion 65 in this order from the power source toward the ground.

The inductor portion 62 is provided with two spiral inductors 62a and 62b. An end of each of the spiral inductors 62a and 62b is coupled to the power source. The other ends of the spiral inductors 62a and 62b are coupled to the output terminals 66a and 66b, respectively.

The variable capacitor portion 63 is provided with two varactors 63a and 63b. One ends of the varactors 63a and 63b (for example, well terminals) are coupled to output terminals 66a and 66b, respectively. The other ends of the varactors 63a and 63b (gate terminal, for example) are coupled to a common control terminal 66c. The configuration of each of the varactors 63a and 63b are similar to that of the varactor 20 shown in FIG. 1.

The thicknesses of the gate insulating films of the varactors 63a and 63b may be equivalent to thicknesses of gate insulating films of transistors 64a, 64b and 65a as discussed later, or may be mutually different. In the case of having different thicknesses of the gate insulating films, the thicknesses of the gate insulating films of varactors 63a and 63b may be larger than, or may be smaller than, the thicknesses of the gate insulating films of the transistors 64a, 64b and 65a. However, if the transistors 64a, 64b and 65a have the gate insulating films, which are the thinnest in the gate insulating films of the transistors provided in the semiconductor substrate that also includes the varactors 63a and 63b, the gate insulating films of the varactors 63a and 63b are formed to be thicker than the gate insulating films of the transistors 64a, 64b and 65a.

The negative resistor portion 64 is provided with the n channel transistors 64a and 64b. A drain and a gate of the transistor 64a are coupled to an output terminal 66a and an output terminal 66b, respectively. A drain and a gate of the transistor 64b are coupled to an output terminal 66b and an output terminal 66a, respectively.

The electric current regulator portion 65 is provided with the n channel transistor 65a. A drain of the transistor 65a is coupled to a source of the transistors 64a and 64b. A source of the transistor 65a is coupled to the ground. A gate of the transistor 65a is also configured to be applied with a bias voltage.

In such LC-VCO 60, an alternating current signal having a frequency equivalent to resonant frequency is created by a resonance phenomenon of a parallel LC tank circuit, which is composed of an inductor portion 62 and a variable capacitor portion 63. The frequency of the created alternating current signal may be controlled by adjusting capacitances of the varactors 63a and 63b. Here, the resonant frequency is defined as a frequency when the reactance of the parallel LC tank circuit is fallen in zero. In addition, the resonance phenomenon is a phenomenon, in which an electric current flows alternately through an inductor and through a variable capacitor (varactor) in a parallel LC tank circuit.

Advantageous effects obtainable by employing the configuration of the present embodiment will be described. In the present embodiment, the gate insulating film 25 of the varactor 20 is formed to be thicker than the gate insulating films 15 and 75 of the transistors 10 and 70. This allows avoiding an excessively thinner thickness of the gate insulating film 25 of the varactor 20 beyond necessity, even if the reduction in the thickness of the gate insulating film of the transistor is progressed. More specifically, an excessively higher tuning sensitivity of the varactor 20 can be avoided. Thus, a semiconductor device 1 comprising the varactor 20, which allows easily achieving a fine tuning of the capacitance, is achieved. In addition to above, in view of obtaining an appropriate tuning sensitivity, the thickness of the gate insulating film 25 may be preferably within a range of from 1.5 nm to 3.5 nm.

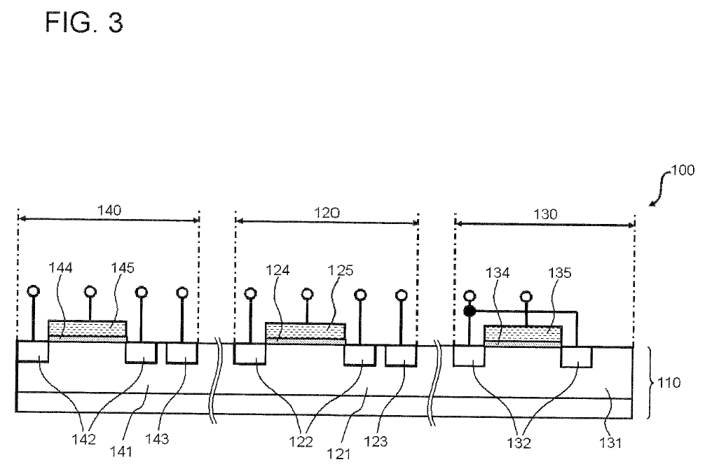

On the contrary, in the conventional semiconductor device shown in FIG. 3, the thickness of the gate insulating film 134 of the varactor 130 is equivalent to that of the gate insulating films 124 and 144 of the transistors 120 and 140. Therefore, an excessive progress in providing thinner thickness of the gate insulating film 134 beyond necessity is caused due to a progress in providing thinner thickness of the gate insulating films 124 and 144 according to an evolution in the process for manufacturing semiconductor devices, leading to a concern in causing a problem of excessively higher tuning sensitivity of the varactor 130. Such problem manifests if the thickness of the thinnest gate insulating film in the gate insulating films of the transistors formed in the semiconductor substrate 110 is smaller than 1.5 nm.

In addition, when the varactor 20 is a varactor that constitutes an LC-VCO (see FIG. 2), excessively higher tuning sensitivity of the varactor 20 causes an enhanced influence of a fluctuation in the voltage input to the varactor 20, causing a problem of a deteriorated jitter noise characteristic of the LC-VCO. Such problem manifests if the product/process are frontier products/frontier processes that exhibit lower source voltage and thinner gate insulating film of transistor.

For example, in a case of employing a high-speed CPU of 90 nm-generation (source voltage is 1 V), variations in the voltages are constantly caused due to a dynamic IR drop, a static IR drop and superimposed source noises. The fluctuation in the voltage to the varactor leads to a fluctuation in the capacitance of the varactor. Then, the fluctuation in the capacitance leads to a fluctuation in the oscillating frequency of the LC-VCO, and eventually to a deterioration of the jitter noise characteristic.

A possible technique for reducing the deterioration of the jitter noise characteristic may be a technique of reducing a fluctuation itself in the voltage input to the varactor by installing a dedicated regulator thereto. However, such technique requires complicated circuit architecture. On the contrary, the present embodiment provides prevention for causing an excessively higher tuning sensitivity of the varactor 20, as described above. This allows reducing a relative fluctuation in the capacitance over the fluctuation in the voltage, so that the deterioration of the jitter noise characteristic can be inhibited without employing a regulator.

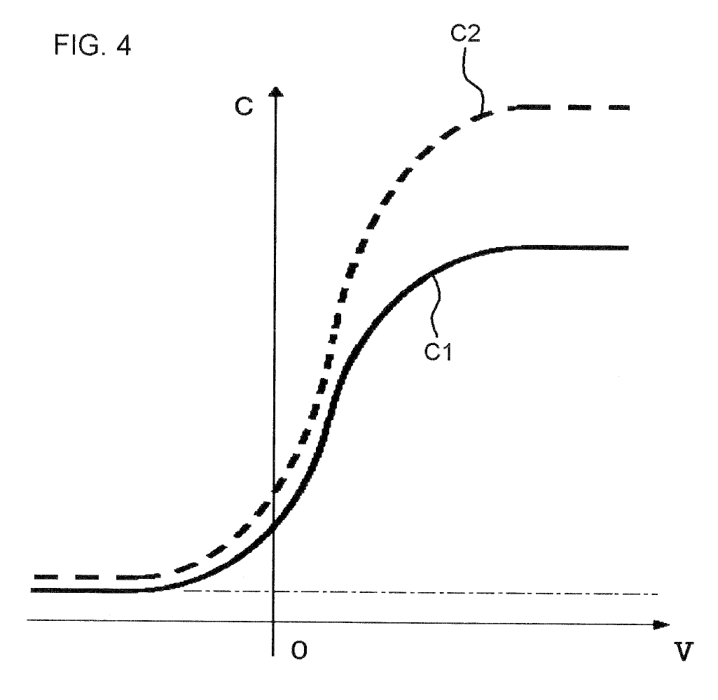

In addition to above, lower tuning sensitivity leads narrower tuning range. If it is necessary to utilize wider tuning range, a capacitive switch, for example, may be employed (see Japanese Patent Laid-Open No. 2004-229,102). In FIG. 6 of Japanese Patent Laid-Open No. 2004-229,102, an LC-VCO further comprising a pair of capacitor elements (each of the capacitor elements has one end connected to an output terminal and the other end connected to ground through a switch element) is disclosed. The pair of capacitor elements described above correspond to a capacitive switch. In more particular, Japanese Patent Laid-Open No. 2004-229,102 discloses the technique for expanding tuning range of LC-VCO by flipping the switch element included in the capacitor switch. The tuning range is defined as a ratio (=Cₘₐₓ/Cₘᵢₙ) of the maximum value of capacitance Cₘₐₓ over the minimum value thereof Cₘᵢₙ. In the above-described FIG. 4, a tuning range for a case of employing a gate insulating film having a thickness of 2.0 nm (line C1) is about 5.0. A tuning range for another case of employing a gate insulating film having a thickness of 1.4 nm (line C1) is about 6.5.

It is intended that the present invention is not limited to the above-described embodiments and various modifications thereof may also be employed. For example, silicon oxynitride (SiON) may be employed for the composition of the gate insulating film of the above-described embodiment, in addition to employing silicon dioxide (SiO₂), or a multiple-layered film may alternatively be employed. In such case, an equivalent oxide thickness (EOT: converted thickness, which is obtained by converting a physical thickness of a film such as a high-dielectric constant film <high-k film> into an electric film thickness that is equivalent to SiO₂ film) of a SiON film or a multiple-layered film satisfies the above-described thicknesses.

It is apparent that the present invention is not limited to the above embodiment, and may be modified and changed without departing from the scope and spirit of the invention.

What is claimed is:

1. A semiconductor device, comprising:
a metal-oxide-semiconductor (MOS) type transistor provided in a semiconductor substrate; and
a MOS type varactor provided in said semiconductor substrate;
wherein a gate insulating film of said varactor is thicker than the thinnest gate insulating film in gate insulating films of said transistor.

2. The semiconductor device as set forth in claim 1, wherein said varactor constitutes an LC resonance-type voltage controlled oscillator.

3. The semiconductor device as set forth in claim 2, wherein said gate insulating film of said varactor is thicker than a gate insulating film of a transistor that constitutes said voltage controlled oscillator.

4. The semiconductor device as set forth in claim 1, wherein an equivalent oxide thickness of said thinnest gate insulating film of said transistor is lower than 1.5 nm.

5. The semiconductor device as set forth in claim 1, wherein said varactor includes a well region of a first type conductivity provided in said semiconductor substrate, a diffusion layer of said first type conductivity provided in said well region and a gate electrode provided on said semiconductor substrate through said gate insulating film.

6. The semiconductor device as set forth in claim 5,
wherein said diffusion layer includes a first diffusion layer of said first type conductivity provided in one side of said gate electrode and a second diffusion layer of said first type conductivity provided in the other side of said gate electrode, and
wherein said first diffusion layer is electrically coupled to said second diffusion layer.
